(19) United States
(12) Patent Application Publication
(10) Pub. No.: US 2008/0149950 A1
(43) Pub. Date: Jun. 26, 2008

(54) Optical communication semiconductor device and method for manufacturing the same

(75) Inventors: Kazuhiko Senda, Kyoto (JP); Shunji Nakata, Kyoto (JP)

Correspondence Address: RABIN & Berdo, PC, 1101 14TH STREET, NW, SUITE 500, WASHINGTON, DC, 20005, US

(73) Assignee: ROHM CO., LTD., Kyoto (JP)

(21) Appl. No.: 11/987,021

(22) Filed: Nov. 26, 2007

(30) Foreign Application Priority Data
Dec. 20, 2006 (JP) P2006-343446

(51) Int. Cl. H01L 33/00

(52) U.S. Cl. 257/90; 438/32; 257/E33.012; 257/E33.068

(57) ABSTRACT

An optical communication semiconductor device including: a first light emitting layer composed of a semiconductor; and a second light emitting layer which is laid on or above the first light emitting layer and composed of a semiconductor capable of emitting light having a emission peak at a wavelength different from that of light emitted by the first light emitting layer.

### CROSS REFERENCE TO RELATED APPLICATIONS AND INCORPORATION BY REFERENCE

This application is based upon and claims the benefit of priority from prior Japanese Patent Application P2006-343446 filed on Dec. 20, 2006; the entire contents of which are incorporated by reference herein.

### BACKGROUND OF THE INVENTION

1. Field of the Invention

The present invention relates to a semiconductor device for optical communication which is capable of emitting light having a plurality of emission peaks at different wavelengths and a method for manufacturing the same.

2. Description of the Related Art

There have been known semiconductor device and unit for optical communication using a plurality of light beams with different wavelengths, at least one of which is used for optical communication.

For example, as described in International Publication WO098/06133 (Patent Literature 1), there is a technique to provide light of two wavelengths using a semiconductor device capable of emitting light having a single emission peak. Specifically, in the case of providing two beams of light having different wavelengths using a semiconductor device which is capable of emitting light having an emission peak at a wavelength of about 900 nm as shown in FIG. 1, the beam of light with a wavelength of about 850 nm, which is shorter than that of the emission peak, is used for optical communication, and the beam of light with a wavelength of about 950 nm, which is longer than that of the emission peak, is used for sensing. The light of two wavelengths can be thus provided using the semiconductor device emitting light having a single emission peak.

Japanese Patent Laid-open Publication No. 2001-77407 (Patent Literature 2) discloses a semiconductor unit including two semiconductor devices and being capable of performing transmission and reception. As an application of the technique of this semiconductor unit, two semiconductor devices capable of emitting beams of light having emission peaks at two different wavelengths (for example, about 850 and 950 nm) are arranged side by side to realize a semiconductor unit which can provide light of two wavelengths.

However, in the case of providing light of two wavelengths using a semiconductor device with a single emission peak as shown in FIG. 1, in order to cause the beams of light with the wavelengths for use to have desired light intensities, the emission intensity of the emission peak (wavelength: about 900 nm) needs to be several times higher than those of light at the wavelengths for use. As a result, the increase in emission intensity raises the temperature of the semiconductor device, thus reducing lifetime of the semiconductor device. Moreover, the intensities or the like of the two beams of light for use can be adjusted by controlling the emission peak shown in FIG. 1. However, adjusting the intensity of one of the beams of light changes the intensity of the other beam of light. It is therefore difficult to independently adjust the intensities of the beams of light.

In the case of the aforementioned semiconductor unit, there is a need to arrange the two semiconductor devices side by side. This increases the semiconductor unit in size and complicates the manufacturing process thereof because of adjustment of optical axes of the two semiconductor devices.

### SUMMARY OF THE INVENTION

An optical communication semiconductor device according to the present invention includes: a first light emitting layer composed of a semiconductor; and a second light emitting layer which is laid on or above the first light emitting layer, composed of a semiconductor and capable of emitting light having a emission peak at a wavelength different from that of light emitted by the first light emitting layer.

A method for manufacturing an optical communication semiconductor device according to the present invention includes: a step of forming a first light emitting layer composed of a semiconductor; and a step of forming a second light emitting layer composed of a semiconductor and capable of emitting light having a emission peak at a wavelength different from that of light emitted from the first light emitting layer after forming the first light emitting layer.

According to the present invention, the provision of the first and second light emitting layers allows emission of light having emission peaks at different wavelengths from the light emitting layers. Moreover, the respective emission peaks of light emitted from the light emitting layers can be set to desired wavelengths. Accordingly, the optical communication semiconductor device does not need a high emission peak at a wavelength other than the desired wavelengths. As a result, the optical communication semiconductor device can be prevented from becoming hot, thus achieving longer lifetime. Moreover, controlling the thicknesses and the compositions of the materials of the first and second light emitting layers allows light emitted from the first and second light emitting layers to be independently adjusted.

Moreover, the provision of the first and second light emitting layers for the optical communication semiconductor device allows the single optical communication semiconductor device to emit two different types of light. Accordingly, the semiconductor device according to the present invention can be reduced in size compared to a semiconductor unit emitting two different types of light from two semiconductor devices. Furthermore, the provision of the first and second light emitting layers for the optical communication semiconductor device eliminates the need to independently adjust the optical axes of light, thus facilitating the manufacturing process of the same.

### BRIEF DESCRIPTION OF THE DRAWINGS

FIG. 1 is a graph showing wavelength and emission intensity in a conventional semiconductor device.

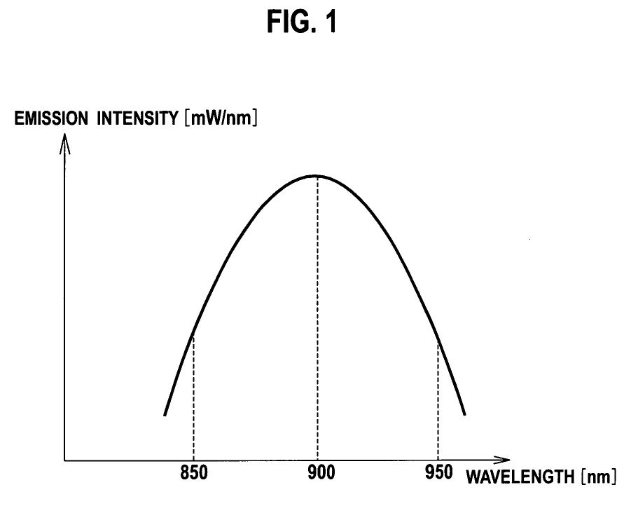

FIG. 2 is a cross-sectional view of a semiconductor device for optical communication according to a first embodiment of the present invention.

FIG. 3 is a cross-sectional view of a semiconductor device for optical communication according to a second embodiment.

FIG. 4 is a cross-sectional view of a semiconductor device according to a comparative example.

FIG. 5 is a graph showing a relation between wavelength and emission intensity in experiment results.

FIG. 6 is a cross-sectional view of a semiconductor device for optical communication according to a modification.

FIG. 7 is a cross-sectional view of a semiconductor device for optical communication according to another modification.

### DETAILED DESCRIPTION OF THE INVENTION

Various embodiments of the present invention will be described with reference to the accompanying drawings. It is to be noted that the same or similar reference numerals are applied to the same or similar parts and elements throughout the drawings, and the description of the same or similar parts and elements will be omitted or simplified.

### First Embodiment

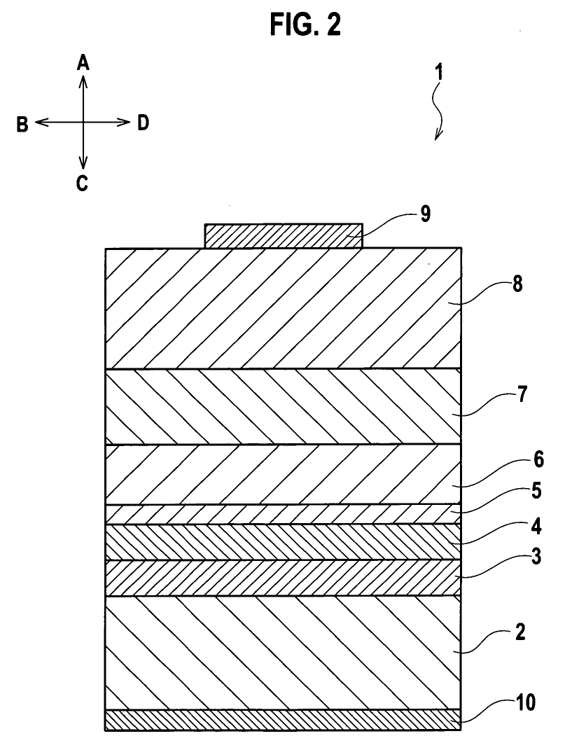

With reference to the drawings, a description is given below of a first embodiment as an application of the present invention to a semiconductor device for optical communication which is capable of emitting light having two wavelengths. FIG. 2 is a cross-sectional view of the semiconductor device for optical communication according to the first embodiment of the present invention.

As shown in FIG. 2, the semiconductor device 1 for optical communication (hereinafter, referred to as a semiconductor device) includes a substrate 2, a reflecting layer 3, an n-type clad layer 4, a first light emitting layer 5, a second light emitting layer 6, a p-type clad layer 7, and a p-type window layer 8 laid on the substrate 2. The semiconductor device 1 further includes a pair of p-side and n-side electrodes 9 and 10, which sandwich the substrate 2 and layers 4 to 8.

The substrate 2 is composed of about 150 μm thick n-type GaAs.

The reflecting layer 3 reflects light which is emitted from the first and second light emitting layers 5 and 6 and travels in a direction of an arrow C and causes the same to travel in a direction of an arrow A (a light irradiation direction). The reflecting layer 3 has a distributed Bragg reflector (DBR) structure in which 10 pairs of alternating about 70 nm thick n-type Al_{0.8}Ga_{0.2}As layers and about 60 nm thick n-type GaAs layers are stacked on each other. The Al_{0.8}Ga_{0.2}As and GaAs layers are doped with silicon as an n-type dopant.

The n-type clad layer 4 is composed of an about 700 nm thick Al_{0.5}Ga_{0.5}As layer doped with silicon as an n-type dopant.

The first light emitting layer 5 emits light for sensing (infrared ray) having an emission peak at a wavelength of about 920 to 970 nm. The first light emitting layer 5 is composed of an about 10 nm thick In_{0.2}Ga_{0.8}As layer.

The second light emitting layer 6 emits light (infrared ray) for IrDA optical communication having an emission peak at a wavelength of about 830 to 870 nm. The second light emitting layer 6 is composed of an about 500 nm thick GaAs layer.

The p-type clad layer 7 is composed of an about 700 nm thick p-type Al_{0.5}Ga_{0.5}As layer doped with zinc as a p-type dopant.

The p-type window layer 8 is provided to distribute holes injected from the p-side electrode in directions of arrows B and D. The p-type window layer 8 reduces the ratio of light blocked by the p-side electrode 9 and reduces the ratio of light reflected on the upper surface of the p-type window layer 8. The p-type window layer 8 is composed of an about 10 μm thick light-transmissive p-type Al_{0.5}Ga_{0.5}As layer doped with zinc as a p-type dopant.

The p-side electrode 9 has a stack structure of a plurality of metallic layers and is formed in an ohmic contact with a part of the upper surface of the p-type window layer 8. The n-side electrode 10 has a stack structure of a plurality of metallic layers and is formed in an ohmic contact with a rear surface of the substrate 2.

Next, a description is given of an operation of the aforementioned semiconductor device.

First, when the semiconductor device 1 is supplied with current through the p-side and n-side electrodes 9 and 10, holes are supplied from the p-side electrode 9, and electrons are supplied from the n-side electrode 10. The holes are injected into the light emitting layers 5 and 6 through the p-type window layer 8 and p-type clad layer 7. Herein, since the p-type window layer 8 is about 10 μm thick, even when the holes are injected from the p-side electrode 9 formed on a part of the upper surface of the p-type window layer 8, the holes are distributed in the directions of the arrows B and D and injected throughout the light emitting layers 6 and 5. The electrons are injected into the light emitting layers 5 and 6 through the substrate 2, reflecting layer 3, and n-type clad layer 4.

The holes and electrons injected into the first light emitting layer 5 are combined to emit the light for sensing having an emission peak at a wavelength of about 920 to 970 nm. The holes and electrons injected to the second light emitting layer 6 are combined to emit the light for IrDA communication having an emission peak at a wavelength of about 830 to 870 nm.

Herein, light traveling in the direction of an arrow C is reflected on the reflecting layer 3 to travel in the direction of the arrow A. The light traveling in the direction of the arrow A is radiated through the p-type clad layer 7 and p-type window layer 8 to the outside. Herein, since the p-type window layer 8 is about 10 μm thick, the ratio of light blocked by the p-side electrode 9 is low. Moreover, the incident angle to the upper surface of the p-type window layer 8 is small, and the ratio of light fully reflected on the same is small. It is therefore possible to increase intensity of the light radiated to the outside.

Next, a description is given of a method for manufacturing the aforementioned semiconductor device.

First, the substrate 2 composed of about 150 μm thick GaAs is introduced into an MOCVD apparatus. Next, trimethylaluminum (hereinafter, referred to as TMA), trimethylgallium (hereinafter, TMG), arusine, and monosilane are supplied with carrier gas (H₂ gas) to form an about 70 nm thick n-type Al_{0.8}Ga_{0.2}As layer doped with silicon. Next, TMG, arusine, and monosilane are supplied with the carrier gas to form an about 60 nm thick n-type GaAs layer doped with silicon. Such a process is repeated to stack 10 pairs of alternating n-type Al_{0.8}Ga_{0.2}As layers and n-type GaAs layers, thus forming the reflecting layer 3.

Next, TMA, TMG, arusine, and monosilane are supplied with the carrier gas to form the n-type clad layer 4 composed of an about 700 nm thick n-type Al_{0.5}Ga_{0.5}As layer doped with silicon.

Next, trimethylindium (hereinafter, TMI), TMG, and arusine are supplied with the carrier gas to form the first light emitting layer 5 composed of an about 10 nm thick In_{0.2}Ga_{0.8}As layer.

Next, TMG and arusine are supplied with the carrier gas to form the second light emitting layer 6 composed of an about 500 nm thick GaAs layer.

Next, TMA, TMG, arusine, and dimethylzinc are supplied with the carrier gas to form the p-type clad layer 7 composed of an about 700 nm thick p-type Al_{0.5}Ga_{0.5}As layer doped with zinc.

Next, TMA, TMG, arusine, and dimethylzinc are supplied with the carrier gas to form the p-type window layer 8 composed of an about 10 μm thick p-type Al_{0.5}Ga_{0.5}As layer doped with zinc.

Next, the p-side electrode 9 is formed on the upper surface of the p-type window layer 8, and the n-side electrode 10 is formed on the rear surface of the substrate 2. Eventually, the thus obtained product is divided into devices, thus completing the semiconductor device 1.

As described above, the semiconductor device 1 includes the two first and second light emitting layers 5 and 6 and is capable of emitting light having emission peaks at different wavelengths from the light emitting layers 5 and 6. The emission peaks of the light emitted from the light emitting layers 5 and 6 can be set to desired wavelengths, and there is no need to set a high emission peak at a wavelength other than the desired wavelengths. The semiconductor device 1 can be therefore prevented from becoming hot because of such a high emission peak, thus achieving longer lifetime. Moreover, by controlling the thicknesses and ratios of materials of the first and second light emitting layers 5 and 6, the intensity of light emitted from the light emitting layers 5 and 6 can be easily adjusted.

Moreover, the semiconductor device 1 includes the two light emitting layers 5 and 6 and can emit light having emission peaks at two different wavelengths by itself. Accordingly, the semiconductor device 1 can be reduced in size compared to a semiconductor unit requiring two semiconductor devices. Moreover, the provision of the two light emitting layers 5 and 6 for the semiconductor device 1 eliminates the need to independently adjust optical axes of beams of light, thus facilitating the manufacturing process of the same.

Furthermore, the provision of the reflecting layer 3 can reduce light absorbed by the substrate 2, thus increasing the intensity of light radiated to the outside.

### Second Embodiment

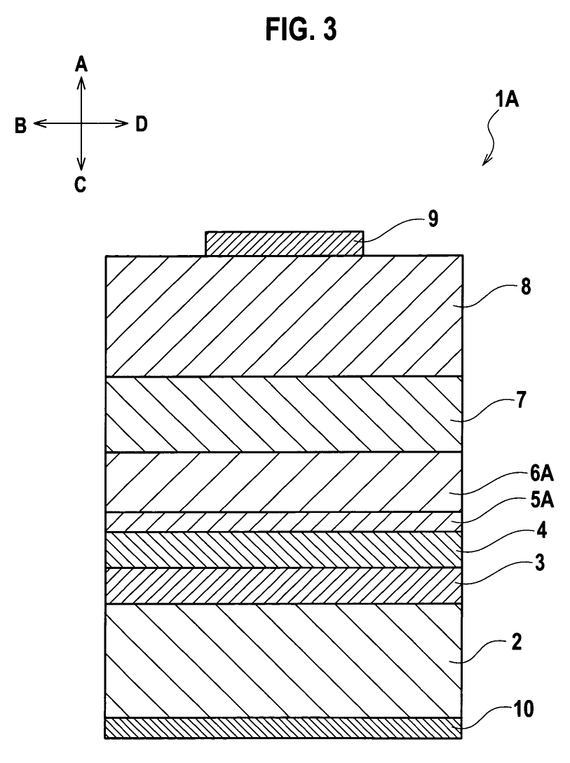

Next, a description is given of a second embodiment obtained by partially modifying the aforementioned first embodiment. FIG. 3 is a cross-sectional view of a semiconductor device for optical communication according to the second embodiment. Similar components to those of the first embodiment are given same reference numerals.

As shown in FIG. 3, a semiconductor device 1A includes first and second light emitting layers 5A and 6A between the n-type clad layer 4 and p-type clad layer 7.

The first light emitting layer 5A is to emit light for IrDA optical communication having an emission peak at a wavelength of about 830 to 870 nm. The first light emitting layer 5A is composed of an about 500 nm thick GaAs layer.

The second light emitting layer 6A is to emit light which is used for sensing having an emission peak at a wavelength of about 920 to 970 nm. The second light emitting layer 6A is composed of an about 20 nm thick In_{0.2}Ga_{0.8}As layer.

The aforementioned second embodiment also includes the two light emitting layers 5A and 6A and can provide similar effects to those of the first embodiment.

Next, a description is given of experiments conducted to prove the effects of the aforementioned first and second embodiments.

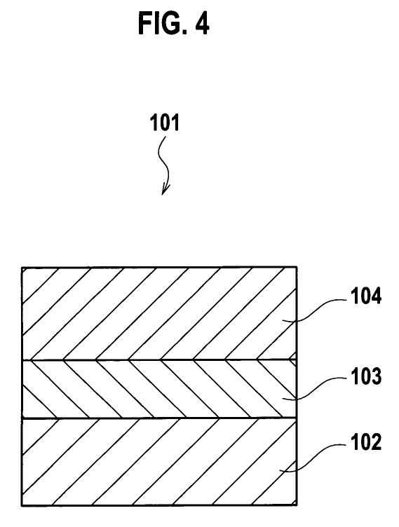

First, the description is given of a semiconductor device of a comparative example manufactured for comparison with the first and second embodiments. FIG. 4 is a cross-sectional view of the semiconductor device of the comparative example.

As shown in FIG. 4, a semiconductor device 101 as the comparative example includes a p-type clad layer 102 composed of an about 140 μm thick p-type AlGaAs layer, a light emitting layer 103 composed of an about 1.0 μm thick GaAs layer, and an n-type clad layer 104 composed of an about 30 μm thick n-type AlGaAs layer.

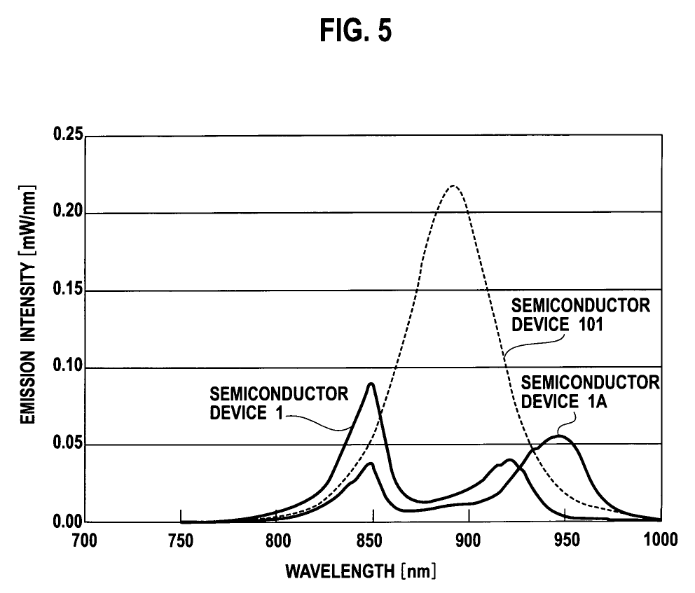

These semiconductor devices 1, 1A, and 101 of the first and second embodiments and comparative example were supplied with current of 50 mA and examined in terms of light emission spectra. Results thereof are shown in FIG. 5. In FIG. 5, the horizontal and vertical axes indicate wavelength [nm] and emission intensity [mW/nm], respectively. The emission intensity in the vertical axis indicates an output [mW] at a certain wavelength [mW].

As shown in FIG. 5, around a wavelength of about 860 nm, which is for IrDA optical communication, the semiconductor devices 1 and 1A had emission intensities of 0.088 and 0.035 mW/nm while the semiconductor device 101 had an emission intensity of about 0.056 mW/nm. Herein, to obtain these emission intensities, the semiconductor device 101 according to the comparative example required an emission intensity of about 0.21 mW/nm at an emission peak (near the wavelength of 895 nm), but the semiconductor devices 1 and 1A according to the present invention did not require such a high emission intensity. As a result, the semiconductor device 101 of the comparative example increases in temperature by light having the aforementioned emission peak. However, the semiconductor devices 1 and 1A does not have such a high emission peak and is prevented from becoming hot. The semiconductor devices 1 and 1A can therefore achieve longer lifetime.

Moreover, as shown in FIG. 5, around the wavelength of about 950 nm, which was used for sensing, the semiconductor device 1A had an emission intensity of about 0.054 mW/nm while the semiconductor device 101 had an emission intensity of about 0.019 mW/nm. Herein, to obtain such emission intensities, the semiconductor device 101 of the comparative example required a high emission peak at a wavelength of about 895 nm, but the semiconductor device 1A of the second embodiment did not require such a high emission peak. As a result, the semiconductor device 101 of the second embodiment can be prevented from becoming hot, thus achieving longer lifetime.

The semiconductor device 101 of the first embodiment has low emission intensity around a wavelength of about 950 nm. However, changing the ratio of In to Ga in the InGaAs layer constituting the first light emitting layer 5 allows the emission peak located around a wavelength of 925 nm to be shifted to a wavelength of about 950 nm. This allows the semiconductor device 101 of the first embodiment to provide similar effects to those of the semiconductor device 1A of the second embodiment.

Hereinabove, the present invention is described in detail using the embodiments but not limited to the embodiments described in this specification. The scope of the present invention is determined based on the scope of claims and their equivalents. In the following, a description is given of modifications obtained by partially modifying the aforementioned embodiments.

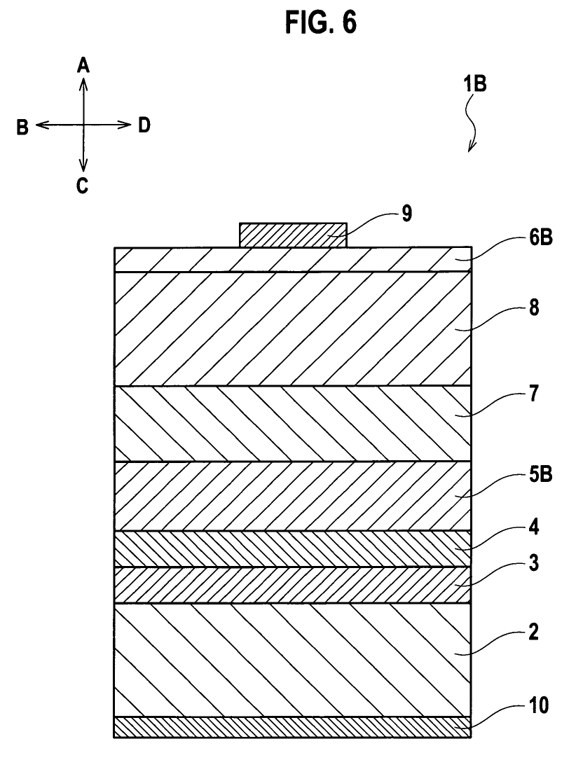

For example, the positions of the light emitting layers can be properly changed. Specifically, like a semiconductor device 1B shown in FIG. 6, a first light emitting layer 5B composed of a GaAs layer may be formed between the n-type and p-type clad layers 4 and 7, and a second light emitting layer 6B composed of a p-type In_{0.2}Ga_{0.8}As layer doped with zinc may be formed between the p-type window layer 8 and p-side electrode 9. In such a structure, when current is supplied through the p-side and n-side electrodes 9 and 10, first, electrons and holes in the first light emitting layer 5B are recombined to emit light having a emission peak at a wavelength of about 830 to 870 nm. When the light is then incident to the second light emitting layer 6B, a part of the light is transmitted, and the other part thereof is converted into light having an emission peak at a wavelength of about 920 to 970 nm in the light emitting layer 6B and then radiated to the outside.

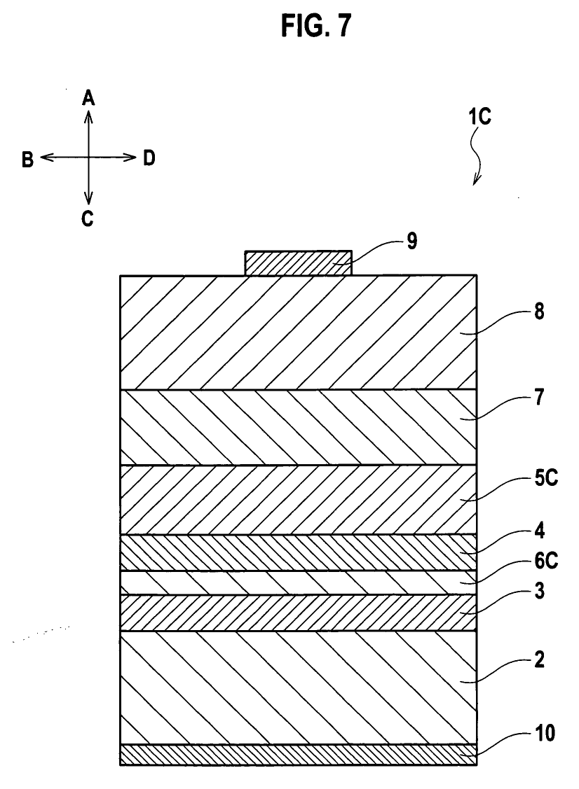

Moreover, like a semiconductor device 1C shown in FIG. 7, a first light emitting layer 5C composed of a GaAs layer may be formed between the n-type and p-type clad layers 4 and 7, and a second light emitting layer 6C composed of a p-type In_{0.2}Ga_{0.8}As layer may be formed between the n-type clad layer 4 and reflecting layer 3. In such a structure, when current is supplied, first, the first light emitting layer 5C emits light with an emission peak at a wavelength of about 830 to 870 nm. When the light is then incident to the second light emitting layer 6C, the light is converted into light having an emission peak at a wavelength of about 920 to 970 nm in the light emitting layer 6C and then radiated to the outside.

Moreover, the materials and thicknesses of the individual layers constituting the semiconductor devices 1 and 1A can be properly changed. For example, the about 10 nm thick In_{0.2}Ga_{0.8}As layer constituting the first light emitting layer 5 may be replaced with an InₓGa₁₋ₓAs layer (0<=x<=0.3) having a thickness of about 5 to 100 nm. The light emitting layer emitting light having an emission peak at a wavelength of about 830 to 870 nm may have an MQW structure in which 80 pairs of alternating about 6 nm thick GaAs layers and about 8 nm thick Al_{0.3}Ga_{0.7}As layers are stacked. Moreover, the reflecting layer 3 may be configured to have a DBR structure in which 5 to 20 pairs of alternating about 50 to 120 nm thick n-type Al_{y}Ga_{1-y}As layers (0≦y≦=1) and about 30 to 100 nm thick n-type GaAs layers are stacked on each other.

Each of the aforementioned semiconductor devices 1 and 1A includes two light emitting layers and is capable of emitting light having two different emission peaks. However, the semiconductor device may include three or more light emitting layers so as to emit light with three different emission peaks.

What is claimed is:

1. An optical communication semiconductor device comprising:
a first light emitting layer composed of a semiconductor; and
a second light emitting layer which is laid on or above the first light emitting layer, composed of a semiconductor and capable of emitting light having a emission peak at a wavelength different from that of light emitted by the first light emitting layer.

2. The device of claim 1, wherein
the second light emitting layer is formed on a light irradiation side of the first light emitting layer.

3. The device of claim 2, wherein
the first light emitting layer emits light for sensing; and
the second light emitting layer emits light for optical communication.

4. The device of claim 3, wherein
light emitted from the first light emitting layer has an emission peak at a wavelength of 920 to 970 nm, and
light emitted from the second light emitting layer has an emission peak at a wavelength of 830 to 870 nm.

5. The device of claim 2, wherein
the first light emitting layer emits light for optical communication and
the second light emitting layer emits light for sensing.

6. The device of claim 5, wherein
light emitted from the first light emitting layer has an emission peak at a wavelength of 830 to 870 nm, and
light emitted from the second light emitting layer has an emission peak at a wavelength of 920 to 970 nm.

7. The device of claim 5, further comprising
a reflecting layer capable of reflecting light emitted from the first and second light emitting layers.

8. The device of claim 7, wherein
the first and second light emitting layers are provided on a light extraction side of the reflecting layer.

9. The device of claim 7, wherein
the reflecting layer has a DBR structure.

10. The device of claim 9, wherein
in the reflecting layer, two types of semiconductor layers having different compositions are alternately stacked on each other cyclically.

11. The device of claim 1, wherein
the substrate is conductive.

12. The device of claim 11, further comprising
an electrode formed on a surface of the substrate opposite to the first and second light emitting layers.

13. A method for manufacturing an optical communication semiconductor device, the method comprising:
a step of forming a first light emitting layer composed of a semiconductor; and
a step of forming a second light emitting layer composed of a semiconductor and capable of emitting light having an emission peak at a wavelength different from that of light emitted from the first light emitting layer after forming the first light emitting layer.

14. The method of claim 13, further comprising
a step of forming a reflecting layer capable of reflecting light emitted from the first and second light emitting layers before forming the first light emitting layer.

15. The method of claim 13, further comprising
a step of alternately stacking two types of semiconductor layers with different compositions on each other cyclically.
